(19) United States
(12) Patent Application Publication
(10) Pub. No.: US 2007/0176204 A1
(43) Pub. Date: Aug. 2, 2007

(54) Field effect transistor

(76) Inventors: Tomohiro Murata, Osaka (JP); Hidetoshi Ishida, Osaka (JP)

Correspondence Address: MCDERMOTT WILL & EMERY LLP, 600 13TH STREET, NW, WASHINGTON, DC, 20005-3096, US

(21) Appl. No.: 11/699,426

(22) Filed: Jan. 30, 2007

(30) Foreign Application Priority Data
Jan. 30, 2006 (JP) 2006-020284
Nov. 16, 2006 (JP) 2006-310131

(51) Int. Cl. H01L 29/15; H01L 31/00; H01L 29/739

(52) U.S. Cl. 257/192; 257/76; 257/194

(57) ABSTRACT

A field effect transistor includes a first semiconductor layer made of a first group III-V nitride; a second semiconductor layer formed on the first semiconductor layer, made of a second group III-V nitride and having a gate recess portion for exposing the first semiconductor layer therein; and a gate electrode formed on the first semiconductor layer in the gate recess portion. A product of stress applied by the second semiconductor layer to the first semiconductor layer and the thickness of the second semiconductor layer is 0.1 N/cm or less.

### CROSS-REFERENCE TO RELATED APPLICATIONS

This application claims priority under 35 U.S.C. §119 on Patent Application No. 2006-020284 filed in Japan on Jan. 30, 2006 and Patent Application No. 2006-310131 filed in Japan on Nov. 16, 2006, the entire contents of which are hereby incorporated by reference.

### BACKGROUND OF THE INVENTION

The present invention relates to a field effect transistor, and more particularly, it relates to a field effect transistor made of a group III-V nitride for use in a high-power and/or high-frequency device.

A group III-V nitride semiconductor, such as gallium nitride (GaN), aluminum nitride (AlN), indium nitride (InN) or a mixed crystal represented by a general formula of (InₓAl₁₋ₓ)_{y}Ga_{1-y}N (wherein 0≦x≦1 and 0≦y≦1), has physical characteristics of a wide band gap and a direct transition type band structure. Therefore, it is applied to an optical device by utilizing the physical characteristics. Furthermore, examination is being made on its application to an electronic device by utilizing other characteristics of a large breakdown electric field and a high saturation electron velocity.

In particular, a heterojunction field effect transistor (hereinafter referred to as the HFET) using a two-dimensional electron gas (hereinafter referred to as the 2DEG) generated on an interface between AlₓGa₁₋ₓN and GaN epitaxially grown on a semi-insulating substrate has been developed as a high-power and/or high-frequency device. The 2DEG of such a GaN-based HFET is composed of electrons supplied from an impurity semiconductor and electrons induced by polarization charge derived from the polarization of the crystal itself (spontaneous polarization) and polarization caused by strain of a lattice (piezo polarization). Accordingly, it is known that the 2DEG of the GaN-based HFET is more largely affected by the stress applied to the lattice than a 2DEG of a gallium arsenide (GaAs)-based HFET composed of merely electrons supplied from an impurity semiconductor.

In order to improve the high-frequency characteristic of a semiconductor device using such a nitride semiconductor, it is necessary to reduce as much as possible a parasitic resistance component such as contact resistance and channel resistance in the semiconductor device. As a method for reducing the contact resistance of an ohmic electrode, a method in which an ohmic electrode is formed on a capping layer made of a GaN layer highly doped with an n-type impurity, a superlattice layer including an AlGaN layer and a GaN layer or the like has been proposed (see, for example, Japanese Laid-Open Patent Publication No. 2005-26671).

Such a conventional semiconductor device in which an ohmic electrode is formed on a capping layer made of an n-type GaN layer, a superlattice layer including an AlGaN layer and a GaN layer or the like has, however, the following problem: It is necessary to form a gate electrode in a gate recess portion formed by removing the capping layer in the conventional semiconductor device. When a gate recess portion is formed, stress is collected at the end of the gate recess portion for a reason described below, and hence, the number of electrons in a channel region is reduced directly beneath the gate recess portion, resulting in increasing the parasitic resistance.

Since GaN is chemically stable, most of etching for this material should be performed by dry process. Since the dry process has a high vertical property, when a gate recess portion is formed by etching a capping layer formed on a barrier layer, a side face of the capping layer corresponding to the sidewall of the gate recess portion becomes substantially vertical to the top face of the barrier layer. Stress caused between the capping layer and the barrier layer is more collected at the end of the gate recess portion as the vertical property of the sidewall is higher. Since the 2DEG of the GaN-based HFET is largely affected by the stress as described above, the electron concentration in the 2DEG channel region is lowered beneath the end of the gate recess portion where the stress is collected. Accordingly, the resistance of the channel region is increased, so as to disadvantageously increase the parasitic resistance.

### SUMMARY OF THE INVENTION

The present invention was devised to overcome the aforementioned conventional problem, and an object of the invention is, in a field effect transistor using a group III-V nitride semiconductor having a gate recess structure, suppressing resistance increase derived from stress caused in a gate recess region, so as to realize a field effect transistor with small parasitic resistance.

In order to achieve the object, the field effect transistor of this invention includes a capping layer in a shape for releasing stress collection at an end of a gate recess portion.

Specifically, the first field effect transistor of the invention includes a first semiconductor layer made of a first group III-V nitride; a second semiconductor layer formed on the first semiconductor layer, made of a second group III-V nitride and having a gate recess portion; a gate electrode formed on the first semiconductor layer in the gate recess portion; and ohmic electrodes formed on the second semiconductor layer on both sides of the gate electrode, and a product of stress applied by the second semiconductor layer to the first semiconductor layer and a thickness of the second semiconductor layer is 0.1 N/cm or less at a gate recess side end of the second semiconductor layer.

In the first field effect transistor, stress applied by the second semiconductor layer working as a capping layer to the first semiconductor layer working as a barrier layer is sufficiently small. Therefore, an electron concentration in a channel region is minimally lowered beneath the gate recess side end of the second semiconductor layer, and hence, the field effect transistor attains small parasitic resistance.

In the first field effect transistor, the second semiconductor layer preferably has a constant thickness.

Alternatively, the second semiconductor layer may have a smaller thickness at the gate recess side end than beneath the ohmic electrodes.

In this case, the second semiconductor layer may have a thickness reduced in a stepwise manner toward the gate recess side end or a continuously reduced thickness in which thickness change becomes gradually smaller toward the gate recess side end.

The second field effect transistor of this invention includes a first semiconductor layer made of a first group III-V nitride; a second semiconductor layer formed on the first semiconductor layer, made of a second group III-V nitride and having a gate recess portion; a gate electrode formed on the first semiconductor layer in the gate recess portion; and ohmic electrodes formed on the second semiconductor layer on both sides of the gate electrode, and a thickness of the second semiconductor layer is reduced toward a gate recess side end thereof in such a manner that thickness change becomes smaller toward the gate recess side end.

In the second field effect transistor, stress applied by the second semiconductor layer to the first semiconductor layer can be dispersed. Therefore, an electron concentration in a channel region is minimally lowered beneath the gate recess side end of the second semiconductor layer, and hence, the field effect transistor attains small parasitic resistance.

In the second field effect transistor, the thickness of the second semiconductor layer is preferably reduced in a stepwise manner. Thus, stress collection at the gate recess side end can be dispersed even when the second semiconductor layer has a large thickness, and at the same time, the resistance of the second semiconductor layer can be reduced, which is necessary for lowering the parasitic resistance of the field effect transistor, owing to the large thickness of the second semiconductor layer.

In the second field effect transistor, the thickness of the second semiconductor layer is preferably continuously reduced. Thus, an angle between the side face of the gate recess side end of the second semiconductor layer and the top face of the first semiconductor layer can be reduced without increasing the width of the gate recess portion. Therefore, the electron concentration in the channel region can be effectively prevented from lowering beneath the gate recess side end of the second semiconductor layer.

The third field effect transistor of this invention includes a first semiconductor layer made of a first group III-V nitride; a second semiconductor layer formed above the first semiconductor layer, made of a second group III-V nitride and having a gate recess portion; a third semiconductor layer that is formed between the second semiconductor layer and the first semiconductor layer, is made of a third group III-V nitride and absorbs stress caused between the second semiconductor layer and the first semiconductor layer; a gate electrode formed on the first semiconductor layer in the gate recess portion; and ohmic electrodes formed on the second semiconductor layer on both sides of the gate electrode.

In the third field effect transistor, stress applied by the second semiconductor layer to the first semiconductor layer can be effectively reduced. Therefore, an electron concentration in a channel region is minimally lowered beneath the gate recess side end of the second semiconductor layer, and hence, the field effect transistor attains small parasitic resistance.

In the third field effect transistor, the third semiconductor layer is preferably made of an amorphous film or a polycrystalline film. Thus, interstitial strain can be definitely absorbed by the third semiconductor layer, so that the stress working between the second semiconductor layer and the first semiconductor layer can be suppressed.

In the third field effect transistor, the third semiconductor layer is preferably grown at a lower growth temperature than the first semiconductor layer. Thus, the third semiconductor layer can be deposited without being influenced by crystal lattice so as to form a low-temperature-grown layer for absorbing the interstitial strain, and hence, the stress can be suppressed.

The fourth field effect transistor of this invention includes a first semiconductor layer made of a first group III-V nitride; a second semiconductor layer formed on the first semiconductor layer, made of a second group III-V nitride and having a gate recess portion; a gate electrode formed on the first semiconductor layer in the gate recess portion; ohmic electrodes formed on the second semiconductor layer on both sides of the gate electrode; and a stress reducing film for covering a bottom and a sidewall of the gate recess portion and causing stress in a direction for cancelling stress applied by the second semiconductor layer to the first semiconductor layer.

In the fourth field effect transistor, stress applied by the second semiconductor layer to the first semiconductor layer can be effectively reduced. Therefore, an electron concentration in a channel region is minimally lowered beneath the gate recess side end of the second semiconductor layer, and hence, the field effect transistor attains small parasitic resistance.

### BRIEF DESCRIPTION OF THE DRAWINGS

FIG. 1 is a cross-sectional view of a field effect transistor according to Embodiment 1 of the invention;

FIG. 2 is a flowchart of a simulation method for a piezoelectric charge density in the field effect transistor of Embodiment 1 of the invention;

FIG. 3 is a graph for showing the correlation between a product of stress and a thickness of a capping layer and an electron concentration in a channel region obtained in the field effect transistor of Embodiment 1;

FIG. 4 is a graph for showing the ranges of the stress of the capping layer and the thickness of the capping layer suitably employed in the field effect transistor of Embodiment 1;

FIG. 5 is a graph for showing the correlation between the thickness of the capping layer and resistance change obtained in the field effect transistor of Embodiment 1;

FIGS. 6A, 6B and 6C are cross-sectional views for showing procedures in a method for fabricating a field effect transistor according to Embodiment 1 of the invention;

FIG. 7 is a cross-sectional view of a field effect transistor according to Embodiment 2 of the invention;

FIGS. 8A, 8B, 8C and 8D are cross-sectional views for showing procedures in a method for fabricating a field effect transistor according to Embodiment 2 of the invention;

FIG. 9 is a cross-sectional view of a field effect transistor according to Embodiment 3 of the invention;

FIG. 10 is a graph for showing influence on stress of an angle between a portion of a capping layer corresponding to a sidewall of a gate recess portion and a top face of a barrier film in the field effect transistor of this invention;

FIGS. 11A, 11B, 11C and 11D are cross-sectional views for showing procedures in a method for fabricating a field effect transistor according to Embodiment 3 of the invention;

FIG. 12 is a cross-sectional view of a field effect transistor according to Embodiment 4 of the invention;

FIGS. 13A, 13B and 13C are cross-sectional views for showing procedures in a method for fabricating a field effect transistor according to Embodiment 4 of the invention;

FIGS. 14A and 14B are respectively a cross-sectional view of a field effect transistor according to Embodiment 5 of the invention and an enlarged cross-sectional view of a gate recess portion thereof;

FIG. 15 is a cross-sectional view of a simulation model used for evaluating a characteristic of the field effect transistor of Embodiment 5 of the invention;

FIGS. 16A and 16B are graphs for respectively showing a stress characteristic and an electron concentration characteristic of the field effect transistor of Embodiment 5 of the invention; and

FIGS. 17A, 17B, 17C and 17D are cross-sectional views for showing procedures in a method for fabricating a field effect transistor according to Embodiment 5 of the invention.

### DETAILED DESCRIPTION OF THE INVENTION

### Embodiment 1

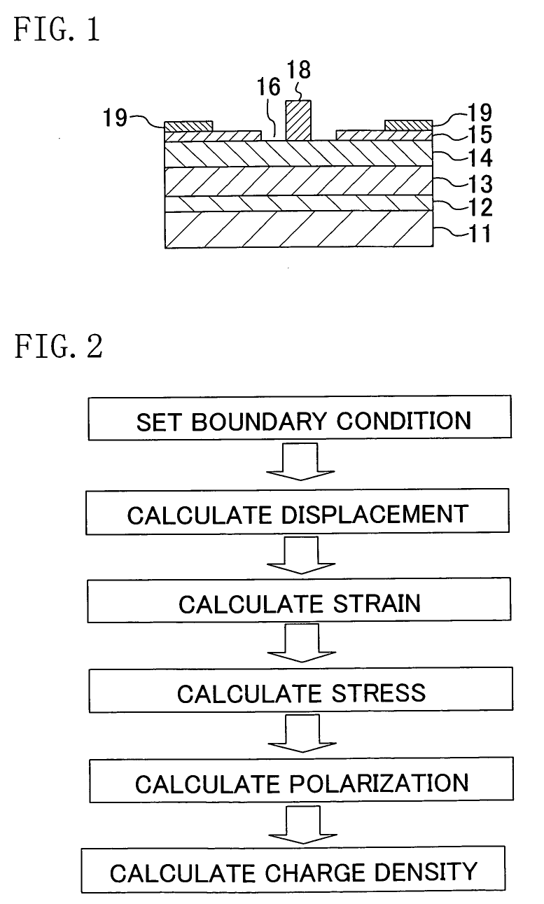

Embodiment 1 of the invention will now be described with reference to the accompanying drawings. FIG. 1 shows the cross-sectional structure of a field effect transistor (FET) according to Embodiment 1. As shown in FIG. 1, a buffer layer 12 made of aluminum nitride (AlN) or gallium nitride (GaN) grown at a low temperature is formed on a substrate 11 of sapphire. An active layer 13 of GaN, a barrier layer 14 of Al_{0.26}Ga_{0.74}N and a capping layer 15 made of a GaN layer doped with an n-type impurity and having lowered resistance are successively formed in this order in the upward direction on the buffer layer 12.

A gate recess portion 16 for exposing the barrier layer 14 therein is formed in the capping layer 15, and a gate electrode 18 is formed on the exposed portion of the barrier layer 14 in the gate recess portion 16. Two ohmic electrodes 19 respectively working as a source electrode and a drain electrode are formed on the capping layer 15 on both sides of the gate electrode 18.

In the FET of this embodiment, the thickness of the capping layer 15 is determined so that a product σt of stress σ applied by the capping layer 15 to the barrier layer 14 and the thickness t of the capping layer 15 can be not more than 0.1 N/cm (10⁴ dyn/cm).

The reason why the product σt is set to 0.1 N/cm or less will now be described. First of all, a method for calculating, by a finite-element method, a piezoelectric charge density induced in the vicinity of a capping layer, which is significant for a GaN-based HFET, will be described.

The piezoelectric charge density in a GaN-based HFET is calculated according to the following Formula (1) (see O. Ambacher et al., “Two-Dimensional electron gases induced by spontaneous and piezoelectric polarization charges in N— and Ga-face AlGaN/GaN heterostructures”, Journal of Applied Physics, 1999, vol. 85, pp. 3222-3233; hereinafter referred to as Non-patent document 1).

P(piezo)=e₃₃ε_{z}+e₃₁(εₓ+ε_{y}) Formula (1)

wherein e₃₃ and e₃₁ are piezoelectric constants, ε_{z} is strain along the c-axis direction, and εₓ and ε_{y} are strain on the c-plane and assumed to be equal to each other. In an actual device, however, it is necessary to consider stress of a capping layer, an insulating film and the like. Piezoelectric formulas are represented as follows:

[T]=[c]:[S]·[e]:[E] Formula (2)

[D]=[e]:[S]·[ε]:[E] Formula (3)

wherein [T] is stress, [c] is an elastic coefficient, [e] is a piezoelectric constant, [E] is an electric field, [D] is an electric flux density, [S] is strain, and [ε] is a dielectric constant. As a boundary condition, it is assumed that stress is applied to the entire end of a capping layer. As a value of the stress, a value measured with a stress gauge in a sample obtained by growing a capping layer on the whole face of a substrate or a sample obtained by depositing an insulating film on the whole face is used. Furthermore, as the elastic coefficient and the piezoelectric constant of a material, Formulas (4) and (5) described below are used. As components of a tensor of AlGaN, values obtained by first-order approximation based on values of GaN and AlN (see Non-patent document 1) are used.

$$Formula ( 4 ) \text{:} \\ [ c ] = ( \begin{matrix}c 11 & c 12 & c 13 & 0 & 0 & 0 \\ c 12 & c 11 & c 13 & 0 & 0 & 0 \\ c 13 & c 12 & c 33 & 0 & 0 & 0 \\ 0 & 0 & 0 & c 44 & 0 & 0 \\ 0 & 0 & 0 & 0 & c 44 & 0 \\ 0 & 0 & 0 & 0 & 0 & ( c 11 - c 12 ) / 2\end{matrix} ) \\ Formula ( 5 ) \text{:} \\ [ e ] = ( \begin{matrix}0 & 0 & 0 & 0 & e 15 & 0 \\ 0 & 0 & 0 & e 15 & 0 & 0 \\ e 31 & e 31 & e 33 & 0 & 0 & 0\end{matrix} ) \qquad$$

In GaN, [c] and [e] of Formulas (4) and (5) are listed in Tables 1 and 2 below.

TABLE 1

| | |
|---|---|
| c11 | 367 GPa |
| c12 | 135 Gpa |
| c13 | 103 Gpa |
| c33 | 405 Gpa |
| c44 | 95 Gpa |

TABLE 2

| | |
|---|---|
| e33 | 0.44 C/m² |
| e31 | −0.22 C/m² |
| e15 | −0.22 C/m² |

The calculation for obtaining a piezoelectric charge density is performed in accordance with a flowchart of FIG. 2. First, in accordance with the boundary condition, displacement at each position of the material is obtained. Next, strain is calculated through partial differentiation of the displacement. Then, stress is calculated by using the strain and the elastic coefficient of the material. Ultimately, polarization obtained on the basis of the piezoelectric constant and the stress is subjected to divergence, thereby calculating a charge density.

Now, a result of simulation performed by the aforementioned manner will be described. FIG. 3 shows the relationship between an electron concentration obtained on the basis of the calculation result of the piezoelectric charge density and the product σt of the stress and the thickness of a capping layer. In FIG. 3, the abscissa indicates the product of the stress and the thickness of the capping layer, and the ordinate indicates a normalized electron concentration in a channel region disposed beneath an end of the capping layer disposed on the side of a gate recess portion (hereinafter referred to as the gate recess side end); A normalized electron concentration is obtained by assuming that an electron concentration attained when the product σt is 0 (zero), namely, when no stress is applied, is 1.

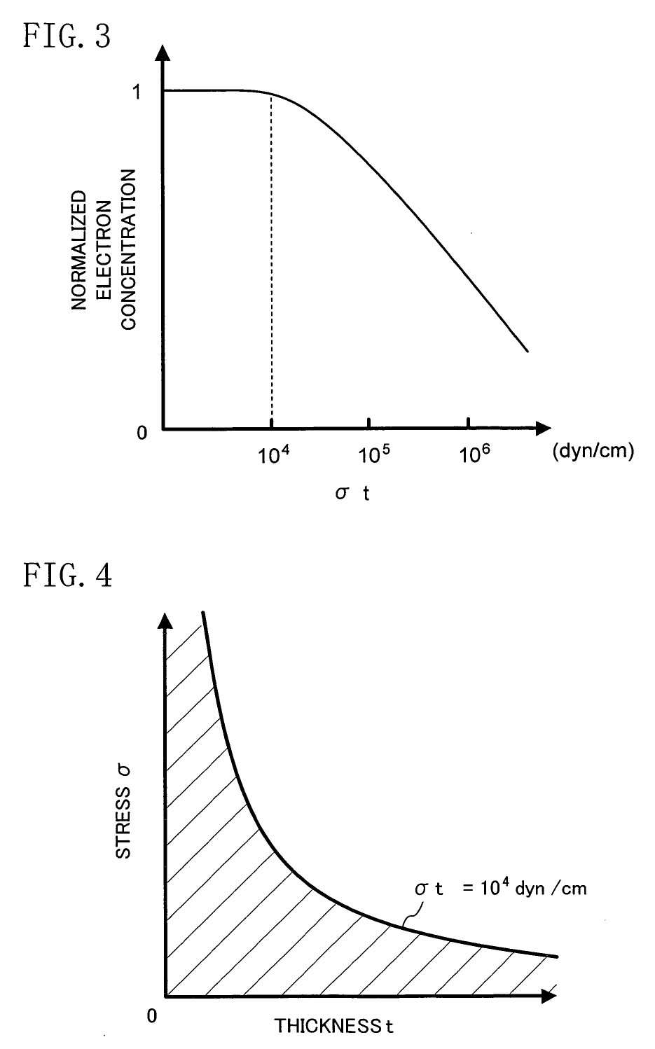

As shown in FIG. 3, the normalized electron concentration in the channel region is abruptly lowered when the product σt is 0.1 N/cm (10⁴ dyn/cm) or more. This is because when the thickness t of the capping layer is large, the total stress applied to the gate recess side end is large even in a system with small stress σ. Therefore, in order not to lower the electron concentration in the channel region, it is significant to reduce the product σt of the stress and the thickness of the capping layer. Specifically, in order not to lower the electron concentration, the stress σ and the thickness t of the material are preferably selected so that the product σt as shown in FIG. 4 can be 0.1 N/cm or less.

Either of the stress σ and the thickness t of the capping layer may be changed, but in general, it is difficult to largely change the stress σ in using the same material, and hence, it is easier to reduce the thickness t of the capping layer. Accordingly, the thickness t of the capping layer is preferably made as small as possible for preventing the lowering of the electron concentration in the channel region.

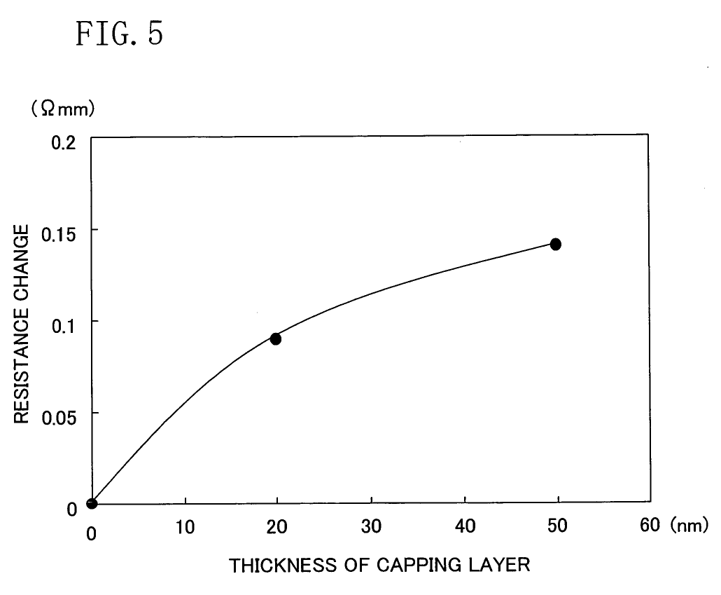

FIG. 5 shows a resistance value obtained between a gate electrode and a source electrode changed by changing the thickness of the capping layer in the simulation. As the thickness of the capping layer is larger, the change of the resistance value is larger. It is obvious also from this result that the thickness t of the capping layer is preferably as small as possible for reducing the parasitic resistance. Accordingly, the thickness t of the capping layer is preferably 20 nm or less.

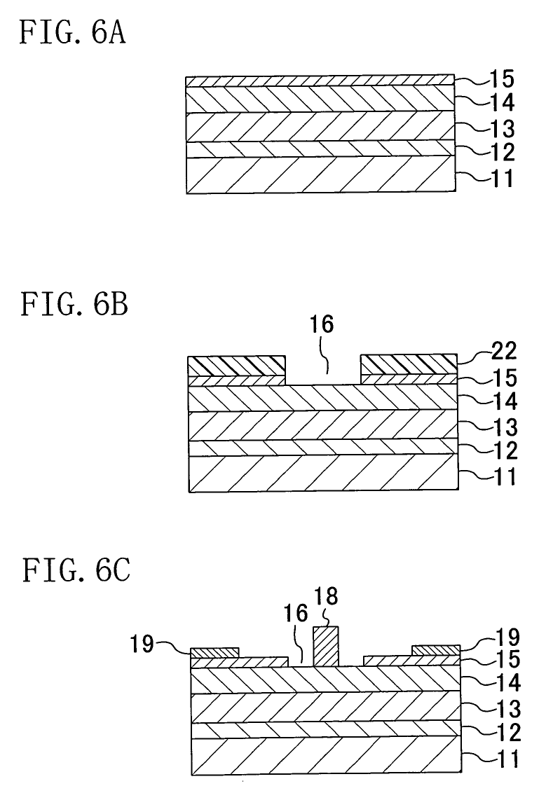

Now, a method for fabricating an FET according to Embodiment 1 will be described with reference to FIGS. 6A through 6C. First, as shown in FIG. 6A, a buffer layer 12 made of AlN or GaN grown at a low temperature is formed on a substrate 11 of sapphire. Subsequently, an active layer 13 of GaN, a barrier layer 14 of Al_{0.26}Ga_{0.74}N and a capping layer 15 made of a GaN layer doped with an n-type impurity and having lowered resistance are successively formed on the buffer layer 12 by metal organic chemical vapor deposition (MOCVD). The capping layer 15 is set so as to attain a product σt of 0.1 N/cm or less as described above. Specifically, the thickness of the capping layer 15 is preferably 20 nm or less, and is 10 nm in this embodiment.

Next, as shown in FIG. 6B, after forming an etching mask 22, a part of the capping layer 15 is removed by dry etching, so as to form a gate recess portion 16.

Then, as shown in FIG. 6C, after removing the etching mask 22, ohmic electrodes 19 are formed on the capping layer 15 so as to sandwich the gate recess portion 16, and a gate electrode 18 is formed on a portion of the barrier layer 14 exposed in the gate recess portion 16. The ohmic electrode 19 is formed by, for example, stacking titanium (Ti) and aluminum (Al), and the gate electrode 18 is formed by, for example, stacking palladium silicon alloy (PdSi), palladium (Pd) and gold (Au).

In order to make the gate electrode 18 Schottky contact with the barrier layer 14, the barrier layer 14 is preferably exposed in the gate recess portion 16 with the capping layer 15 completely removed therein. However, the capping layer 15 may slightly remain beneath the gate electrode 18 as far as the gate electrode 18 can be normally operated. Also, the capping layer 15 may be made of a superlattice layer in which thin films of AlGaN and GaN are alternately stacked, an InAlGaN layer or the like instead of the GaN layer.

As the etching mask 22, a material, such as an organic resist, having dry etch selectivity of 2 or less against a group III-V nitride semiconductor is preferred to a material, such as SiO₂, having high dry etch selectivity against the semiconductor. For example, when a resist mask is used and exposure and development are carried out under conditions for making a resultant resist pattern have a cross-section in a forward tapered shape, the mask material is simultaneously etched in the dry etching. Therefore, the shape of the end portion of the resist pattern can be directly transferred onto the semiconductor, and hence, the gate recess side end can be formed in a forward tapered shape. When the end of the capping layer is in a forward tapered shape, stress collection can be reduced as described below, and hence, such a method is effective for reducing the parasitic resistance.

### Embodiment 2

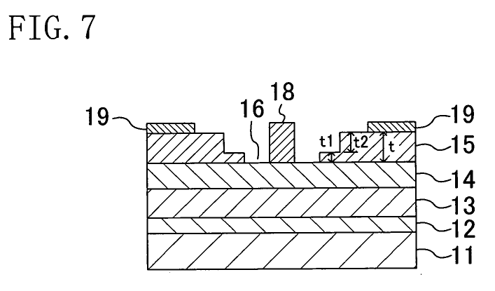

Embodiment 2 of the invention will now be described with reference to the accompanying drawing. FIG. 7 shows the cross-sectional structure of an FET according to Embodiment 2 of the invention. In FIG. 7, like reference numerals are used to refer to like elements used in FIG. 1 so as to omit the description.

As shown in FIG. 7, in the FET of this embodiment, a capping layer 15 has a smaller thickness at a gate recess side end thereof than beneath an ohmic electrode 19. In other words, the thickness of the capping layer 15 is changed to be reduced in a stepwise manner toward the gate recess side end. The stress applied by the capping layer 15 to a barrier layer 14 is collected beneath a portion where the thickness of the capping layer 15 is changed, and the stress is larger as the change in the thickness of the capping layer 15 is larger. Accordingly, when the thickness of the capping layer 15 is changed in a stepwise manner, the stress applied by the capping layer 15 to the barrier layer 14 can be dispersed. When the stress is dispersed, the electron concentration in a channel region can be prevented from abruptly lowering beneath the gate recess side end of the capping layer 15, and hence, increase of the parasitic resistance can be suppressed. Furthermore, since the capping layer 15 has a sufficiently large thickness beneath the ohmic electrode 19, it is not apprehended that the contact resistance of the ohmic electrode 19 is increased.

It is the thickness change of the gate recess side end of the capping layer 15 that most largely affects the lowering of the electron concentration in the channel region. Accordingly, the thickness change of the capping layer 15 is preferably smallest at the gate recess side end, and is more preferably made gradually smaller toward the gate recess side end. In the case where the thickness of the capping layer 15 is changed in, for example, two stages, the thickness change of the gate recess side end of the capping layer 15, namely, the thickness t1 of the gate recess side end of the capping layer 15, is preferably smaller than the thickness change t2 of the other portion. Also, the thickness t1 is preferably set so that a product σt1 of the stress σ and the thickness t1 can be 0.1 N/cm or less.

The thickness of the capping layer 15 may be changed in three or more stages instead of the two stages. When the thickness is changed in multiple stages, the stress can be further dispersed. Also in this case, the thickness change is preferably the smallest in a portion closest to the gate electrode.

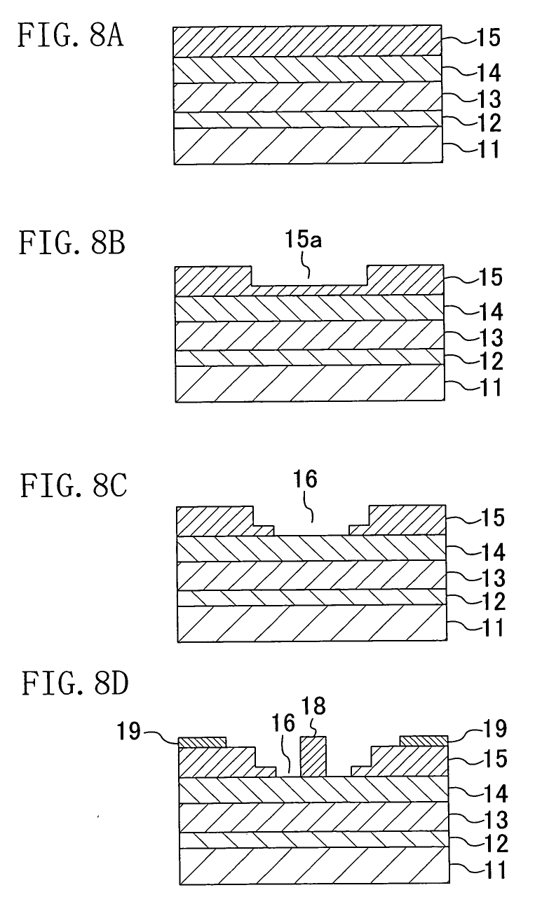

Now, a method for fabricating an FET according to Embodiment 2 of the invention will be described with reference to FIGS. 8A through 8D. First, as shown in FIG. 8A, a buffer layer 12 made of AlN or GaN grown at a low temperature is formed on a substrate 11 of sapphire. Subsequently, an active layer 13 of GaN, a barrier layer 14 of Al_{0.26}Ga_{0.74}N and a capping layer 15 made of a GaN layer doped with an n-type impurity and having lowered resistance are successively formed on the buffer layer 12 by the metal organic chemical vapor deposition (MOCVD). In this embodiment, the capping layer 15 has a thickness of 70 nm.

Next, as shown in FIG. 8B, the capping layer 15 is selectively dry etched into a thickness of 10 nm so as to form a recess 15a.

Then, as shown in FIG. 8C, the bottom of the recess 15a is further etched, so as to form a gate recess portion 16 for exposing the barrier layer 14 therein.

Next, as shown in FIG. 8D, a gate electrode 18 is formed on a portion of the barrier layer 14 exposed in the gate recess portion 16, and ohmic electrodes 19 are formed on the capping layer 15 so as to sandwich the gate electrode 18.

In order to make the gate electrode 18 Schottky contact with the barrier layer 14, the barrier layer 14 is preferably exposed in the gate recess portion 16 with the capping layer 15 completely removed therein. However, the capping layer 15 may slightly remain beneath the gate electrode 18 as far as the gate electrode 18 can be normally operated. Also, the capping layer 15 may be made of a superlattice layer in which thin films of AlGaN and GaN are alternately stacked, an InAlGaN layer or the like instead of the GaN layer.

Also in this embodiment, in the same manner as in Embodiment 1, as the etching mask, a material, such as an organic resist, having dry etch selectivity of 2 or less against a group III-V nitride semiconductor is preferred to a material, such as SiO₂, having high dry etch selectivity against the semiconductor. For example, when a resist mask is used and exposure and development are carried out under conditions for making a resultant resist pattern have a cross-section in a forward tapered shape, the mask material is simultaneously etched in the dry etching. Therefore, the shape of the end portion of the mask can be directly transferred onto the semiconductor, and hence, the end of the capping layer 15 can be formed in a forward tapered shape. When the end of the capping layer 15 is in a forward tapered shape, stress collection can be reduced as described below, and hence, such a method is effective for reducing the parasitic resistance.

### Embodiment 3

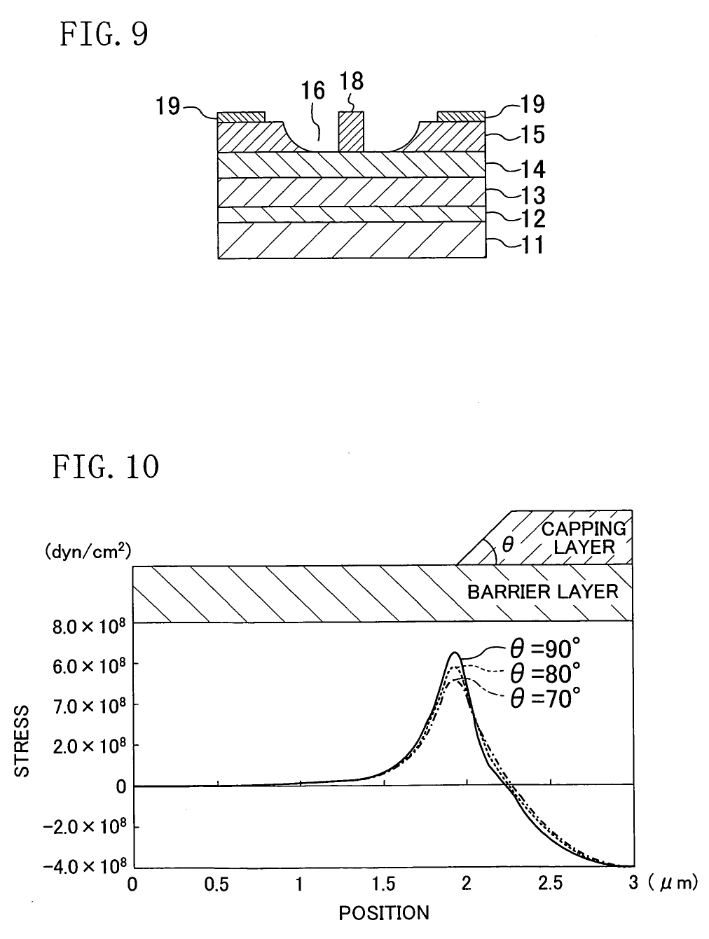

Embodiment 3 of the invention will now be described with reference to the accompanying drawings. FIG. 9 shows the cross-sectional structure of an FET according to Embodiment 3 of the invention. In FIG. 9, like reference numerals are used to refer to like elements shown in FIG. 1 so as to omit the description.

As shown in FIG. 9, as a characteristic of the FET of this embodiment, a portion of a capping layer 15 corresponding to a sidewall of a gate recess portion 16 is nonlinearly reduced in the thickness in a downward convex curve so that the thickness change can be smaller toward a gate recess side end thereof. The FET of this embodiment may be regarded as one FET of Embodiment 2 where the thickness of the capping layer is changed in infinite stages.

The stress collection at the gate recess side end of the capping layer 15 is larger as an angle θ between the side face of the gate recess side end of the capping layer 15 and the top face of a barrier layer 14 is closer to a right angle. FIG. 10 shows results of simulation performed for obtaining stress while changing the angle θ between the side face of the gate recess side end of the capping layer 15 and the top face of the barrier layer 14. In FIG. 10, the abscissa indicates the position and the ordinate indicates the stress. It is understood from FIG. 10 that the stress is collected at the gate recess side end of the capping layer 15 and that the stress collection is released by reducing the angle θ between the side face of the gate recess side end of the capping layer 15 and the top face of the barrier layer 14.

Accordingly, the angle θ between the side face of the gate recess side end of the capping layer 15 and the top face of the barrier layer 14 is preferably as small as possible. When the angle θ is small, however, the width of the gate recess portion 16 is disadvantageously large. On the other hand, a portion significant for reducing the stress collection is the end of the capping layer 15, and the stress collection can be released by reducing the angle θ at the gate recess side end of the capping layer 15. Therefore, in this embodiment, the thickness of the capping layer 15 is changed so that the capping layer 15 can be in a nonlinear shape slightly rounded at the gate recess side end. Since the thickness of the capping layer 15 is thus nonlinearly reduced so that the thickness change is gradually reduced toward the gate recess side end, the angle θ between the side face of the gate recess side end of the capping layer 15 and the top face of the barrier layer 14 can be made substantially 0 degrees. As a result, the stress can be more effectively dispersed, and the electron concentration in a channel region can be efficiently prevented from lowering beneath the gate recess side end of the capping layer 15, and hence, the increase of the parasitic resistance can be suppressed.

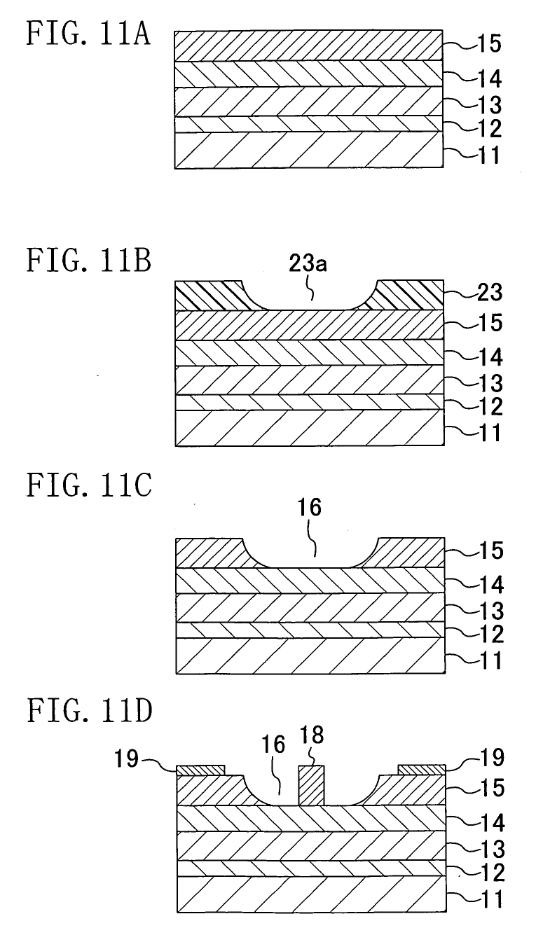

Now, a method for fabricating an FET according to Embodiment 3 of the invention will be described with reference to FIGS. 11A through 11D. First, as shown in FIG. 11A, a buffer layer 12 made of AlN or GaN grown at a low temperature is formed on a substrate 11 of sapphire. Subsequently, an active layer 13 of GaN, a barrier layer 14 of Al_{0.26}Ga_{0.74}N and a capping layer 15 made of a GaN layer doped with an n-type impurity and having lowered resistance are successively formed on the buffer layer 12 by the metal organic chemical vapor deposition (MOCVD). In this embodiment, the capping layer 15 has a thickness of 70 nm.

Next, as shown in FIG. 11B, after depositing a silicon film 23 on the capping layer 15 by vacuum deposition or sputtering, an opening 23a for exposing the capping layer 15 therein is formed. The opening 23a is formed as follows: A recess pattern is formed on the silicon film 23 by lithography, and with the recess pattern used as a mask, the silicon film 23 is wet etched with an etching solution of a mixture of hydrofluoric acid, nitric acid and water (or acetic acid). Owing to the isotropy of the wet etching, the thickness of the silicon film 23 on the sidewall of the opening 23a can be nonlinearly reduced.

Then, as shown in FIG. 11C, the capping layer 15 is dry etched by using the silicon film 23 as a mask. Since the silicon film 23 is also etched during the dry etching, a slightly rounded nonlinear shape having been formed in the silicon film 23 is transferred to the capping layer 15. Thus, the portion of the capping layer 15 corresponding to the sidewall of the gate recess portion 16 is monotonically and nonlinearly reduced in the thickness so as to be formed in a slightly rounded nonlinear shape.

Next, as shown in FIG. 11D, a gate electrode 18 is formed on a portion of the barrier layer 14 exposed in the gate recess portion 16, and ohmic electrodes 19 are formed on the capping layer 15 so as to sandwich the gate electrode 18.

In order to make the gate electrode 18 Schottky contact with the barrier layer 14, the barrier layer 14 is preferably exposed in the gate recess portion 16 with the capping layer 15 completely removed therein. However, the capping layer 15 may slightly remain beneath the gate electrode 18 as far as the gate electrode 18 can be normally operated. Also, the capping layer 15 may be made of a superlattice layer in which thin films of AlGaN and GaN are alternately stacked, an InAlGaN layer or the like instead of the GaN layer.

Although the silicon film 23 is used as the etching mask in forming the gate recess portion 16 in this embodiment, a silicon oxide (SiO₂) film, a silicon nitride (SiN) film, a silicon oxynitride (SiON) film or a multilayered film including any of these films may be used instead of the silicon film. In the case where the multilayered film is used as the etching mask, the wet etching for forming the etching mask is carried out by using buffered hydrofluoric acid.

### Embodiment 4

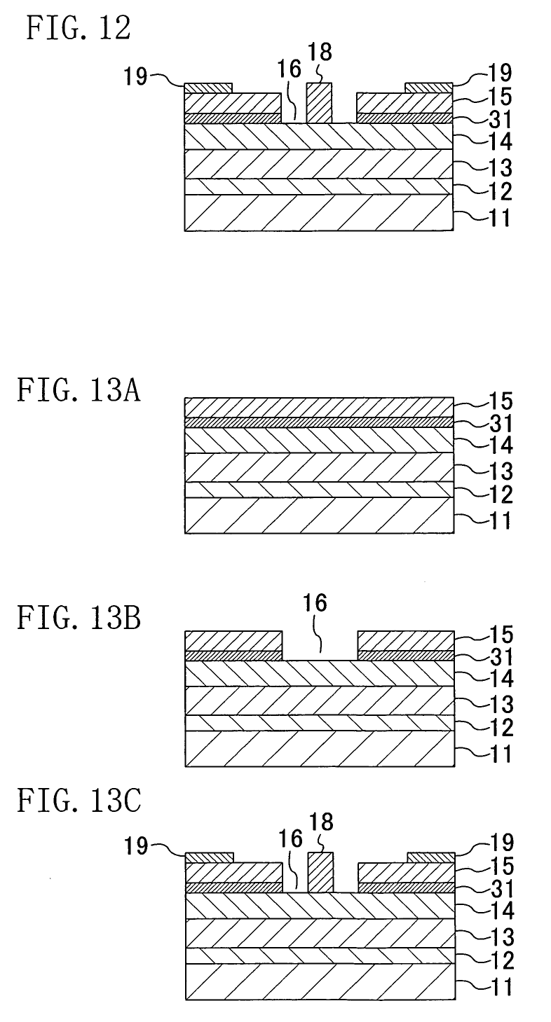

Embodiment 4 of the invention will now be described with reference to the accompanying drawings. FIG. 12 shows the cross-sectional structure of an FET according to Embodiment 4 of the invention. In FIG. 12, like reference numerals are used to refer to like elements used in FIG. 1 so as to omit the description.

As shown in FIG. 12, the FET of this embodiment includes a stress releasing layer 31 between a barrier layer 14 and a capping layer 15. The stress releasing layer 31 is an n-type low-temperature grown GaN layer grown at a comparatively low temperature of approximately 500° C. through 600° C. Since the stress releasing layer 31 reduces adverse influence of lattice mismatch between the barrier layer 14 and the capping layer 15, it absorbs stress caused by forming the capping layer 15 above the barrier layer 14. Accordingly, the electron concentration in a channel region can be efficiently prevented from lowering beneath a gate recess side end of the capping layer 15 by forming the stress releasing layer 31. As a result, the increase of the parasitic resistance of the FET can be suppressed.

Now, a method for fabricating an FET according to Embodiment 4 of the invention will be described with reference to FIGS. 13A through 13C. First, as shown in FIG. 13A, a buffer layer 12 made of AlN or GaN grown at a low temperature is formed on a substrate 11 of sapphire. Subsequently, an active layer 13 of GaN, a barrier layer 14 of Al_{0.26}Ga_{0.74}N, a stress releasing layer 31 made of an n-type low-temperature-grown GaN layer grown at a comparatively low temperature of approximately 500° C. through 600° C. and a capping layer 15 made of a GaN layer doped with an n-type impurity and having reduced resistance are successively formed on the buffer layer 12 by the metal organic chemical vapor deposition (MOCVD). In this embodiment, the stress releasing layer 31 has a thickness of 10 nm.

Then, as shown in FIG. 13B, after forming an etching mask (not shown), the capping layer 15 and the stress releasing layer 31 are selectively removed by the dry etching, so as to form a gate recess portion 16. In order to make a gate electrode Schottky contact with the barrier layer 14, the barrier layer 14 is preferably exposed in the gate recess portion 16 with the stress releasing layer 31 completely removed therein. However, the stress releasing layer 31 may slightly remain beneath the gate electrode as far as the gate electrode can be normally operated.

Next, as shown in FIG. 13C, a gate electrode 18 is formed on the portion of the barrier layer 14 exposed in the gate recess portion 16, and ohmic electrodes 19 are formed on the capping layer 15 so as to sandwich the gate electrode 18.

It is noted that the capping layer 15 may be made of a superlattice layer in which an AlGaN thin film and a GaN thin film are alternately stacked or an InAlGaN film instead of the GaN layer. Also, the stress releasing layer 31 may be made of a crystalline AlN layer, a polycrystalline or amorphous GaN, AlGaN, InGaN or InAlGaN layer or a multilayered film including any of these layers instead of the n-type low-temperature-grown GaN layer.

### Embodiment 5

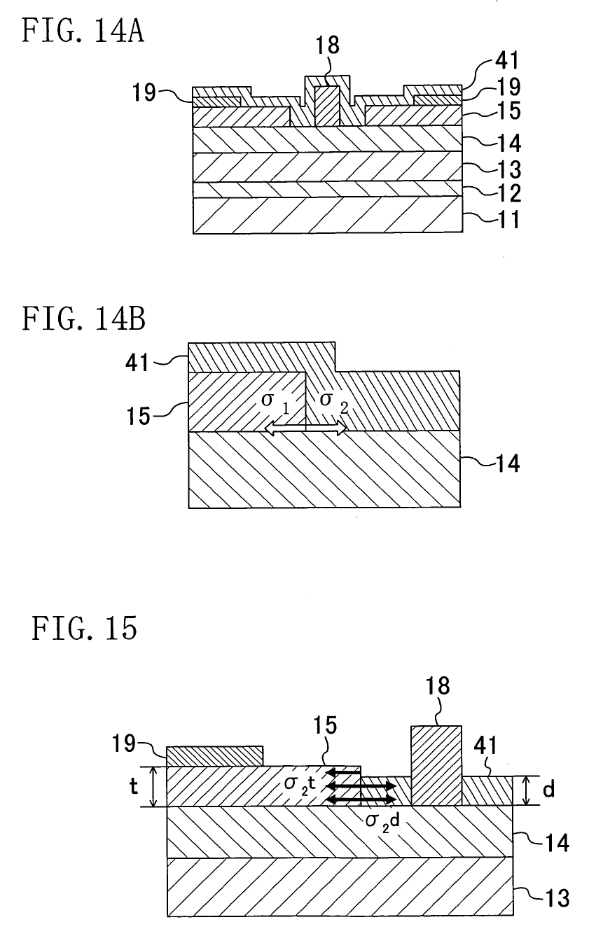

Embodiment 5 of the invention will now be described with reference to the accompanying drawings. FIGS. 14A and 14B show the cross-sectional structure of an FET according to Embodiment 5 of the invention, and specifically, FIG. 14A is a cross-sectional view of the whole FET and FIG. 14B is an enlarged cross-sectional view of the vicinity of a gate recess portion thereof. In FIGS. 14A and 14B, like reference numerals are used to refer to like elements shown in FIG. 1 so as to omit the description.

As shown in FIGS. 14A and 14B, the FET of this embodiment includes a stress reducing film 41 covering a region including at least the bottom and the sidewall of the gate recess portion. The stress reducing film 41 applies, to a barrier layer 14, stress σ2 in a direction for cancelling stress σ1 applied by a capping layer 15 to the barrier layer 14 at the gate recess side end of the capping layer 15 as shown in FIG. 14B. Accordingly, since the stress σ1 applied by the capping layer 15 and the stress σ2 applied by the stress reducing film 41 cancel each other, the electron concentration in a channel region can be efficiently prevented from lowering beneath the gate recess side end of the capping layer 15. As a result, the increase of the parasitic resistance of the FET can be suppressed.

The stress reducing film 41 may be made of, for example, a SiN film, a SiO₂ film, a SiNO film or a multilayered film including any of these films. Also, the thickness of the stress reducing film 41 is preferably approximately 500 nm. Thus, the stress can be reduced by approximately 0.2 N/cm².

Now, the effect of the stress reducing film 41 confirmed through simulation will be described. FIG. 15 shows a simulation model used for obtaining a piezoelectric charge density in the FET of this embodiment. In FIG. 15, σ1 indicates the stress applied by the capping layer 15, σ2 indicates the stress applied by the stress reducing film 41, t indicates the thickness of the capping layer 15, d indicates the thickness of the stress reducing film 41, σ1t indicates a force applied by the capping layer 15 to the barrier layer 14, and σ2d indicates a force applied by the stress reducing film 41 to the barrier layer 14.

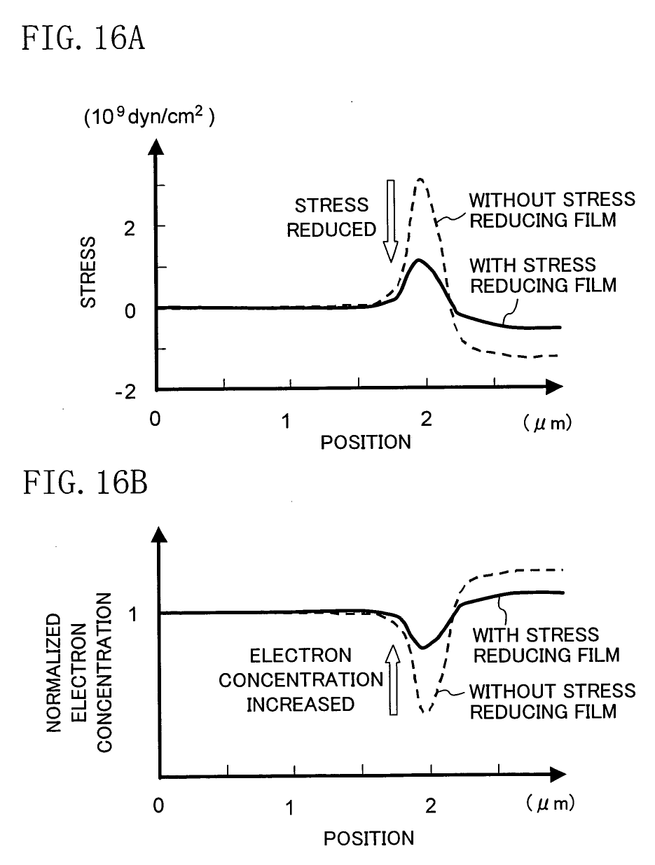

The stress applied to the barrier layer 14 obtained by using the model of FIG. 15 is shown in FIG. 16A. In FIG. 16A, the abscissa indicates a position in the gate recess portion 16 away from the end of a gate electrode 18, and the end of the capping layer 15 is in a position away from the gate electrode 18 by a distance of 2 μm. The stress is collected in the vicinity of the end of the capping layer 15, and when the stress reducing film 41 is provided, the stress collection is reduced as compared with the case where the stress reducing film 41 is not provided. This is because the tension σ1t applied by the capping layer 15 to the barrier layer 14 and the tension σ2t applied by the stress reducing film 41 to the barrier layer 14 cancel each other, so as to reduce the whole stress.

FIG. 16B shows change of the electron concentration in a channel region. In FIG. 16B, the abscissa indicates the position in the gate recess portion 16 in the same manner as in FIG. 16A, and the ordinate indicates a normalized electron concentration. In this case, the normalized electron concentration is obtained by assuming that the electron concentration attained when the stress is 0 is 1.

As shown in FIG. 16B, the electron concentration in the channel region is lowered in the vicinity of the end of the capping layer 15 where the stress is collected and is applied to the barrier layer 14. When the stress reducing film 41 is provided, however, the lowering of the electron concentration can be obviously suppressed as compared with the case where the stress reducing film 41 is not provided.

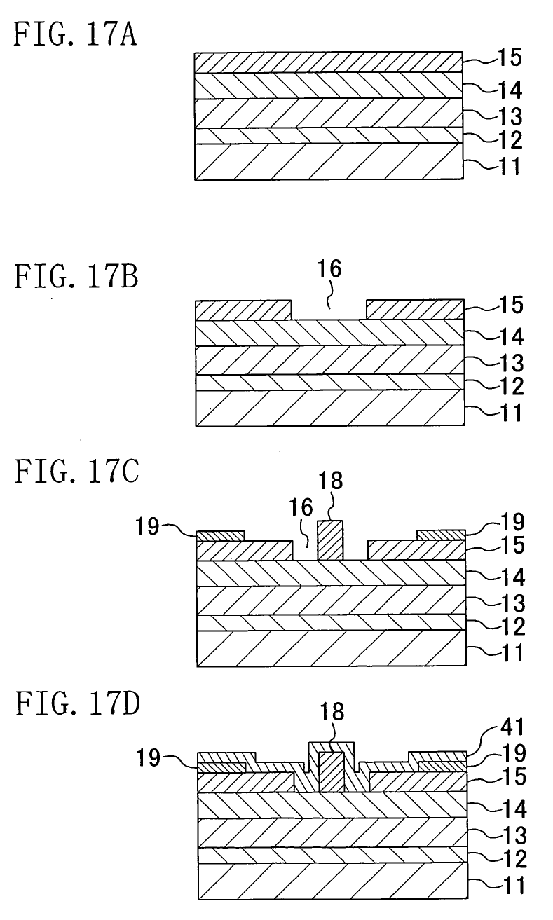

Now, a method for fabricating an FET according of Embodiment 5 will be described with reference to FIGS. 17A through 17D. First, as shown in FIG. 17A, a buffer layer 12 made of AlN or GaN grown at a low temperature is formed on a substrate 11 of sapphire. Subsequently, an active layer 13 of GaN, a barrier layer 14 of Al_{0.26}Ga_{0.74}N and a capping layer 15 made of a GaN layer doped with an n-type impurity and having lowered resistance are successively formed on the buffer layer 12 by the metal organic chemical vapor deposition (MOCVD).

Next, as shown in FIG. 17B, after forming an etching mask (not shown), the capping layer 15 is selectively removed by the dry etching or the like, so as to form a gate recess portion 16.

Then, as shown in FIG. 17C, a gate electrode 18 is formed on a portion of the barrier layer 14 exposed in the gate recess portion 16, and ohmic electrodes 19 are formed on the capping layer 15 so as to sandwich the gate electrode 18.

Next, as shown in FIG. 17D, a stress reducing film 41 that is made of a SiN film, a SiO₂ film, a SiNO film or a multilayered film including any of these films and has stress along a direction for cancelling the stress applied by the capping layer 15 to the barrier layer 14 is deposited in a thickness of, for example, 500 nm so as to cover at least the bottom and the sidewall of the gate recess portion 16.

In order to make the gate electrode 18 Schottky contact with the barrier layer 14, the barrier layer 14 is preferably exposed in the gate recess portion 16 with the capping layer 15 completely removed therein. However, the capping layer 15 may slightly remain beneath the gate electrode 18 as far as the gate electrode 18 can be normally operated. Also, the capping layer 15 may be made of a superlattice layer in which thin films of AlGaN and GaN are alternately stacked, an InAlGaN layer or the like instead of the GaN layer.

As described so far, according to a field effect transistor using a group III-V nitride semiconductor of this invention, resistance increase owing to the influence of stress caused in a gate recess portion is suppressed, and hence, a field effect transistor with small parasitic resistance can be realized. Therefore, the present invention is useful for, for example, a field effect transistor made of a group III-V nitride semiconductor for use in a high-frequency device in particular.

What is claimed is:

1. A field effect transistor comprising:
a first semiconductor layer made of a first group III-V nitride;
a second semiconductor layer formed on said first semiconductor layer, made of a second group III-V nitride and having a gate recess portion;
a gate electrode formed on said first semiconductor layer in said gate recess portion; and
ohmic electrodes formed on said second semiconductor layer on both sides of said gate electrode,
wherein a product of stress applied by said second semiconductor layer to said first semiconductor layer and a thickness of said second semiconductor layer is 0.1 N/cm or less at a gate recess side end of said second semiconductor layer.

2. The field effect transistor of claim 1,
wherein said second semiconductor layer has a constant thickness.

3. The field effect transistor of claim 1,
wherein said second semiconductor layer has a smaller thickness at the gate recess side end than beneath said ohmic electrodes.

4. The field effect transistor of claim 3,
wherein said second semiconductor layer has a thickness reduced in a stepwise manner toward the gate recess side end.

5. The field effect transistor of claim 3,
wherein said second semiconductor layer has a continuously reduced thickness in which thickness change becomes gradually smaller toward the gate recess side end.

6. A field effect transistor comprising:
a first semiconductor layer made of a first group III-V nitride;
a second semiconductor layer formed on said first semiconductor layer, made of a second group III-V nitride and having a gate recess portion;
a gate electrode formed on said first semiconductor layer in said gate recess portion; and
ohmic electrodes formed on said second semiconductor layer on both sides of said gate electrode,
wherein a thickness of said second semiconductor layer is reduced toward a gate recess side end thereof in such a manner that thickness change becomes smaller toward the gate recess side end.

7. The field effect transistor of claim 6,
wherein the thickness of said second semiconductor layer is reduced in a stepwise manner.

8. The field effect transistor of claim 6,
wherein the thickness of said second semiconductor layer is continuously reduced.

9. A field effect transistor comprising:
a first semiconductor layer made of a first group III-V nitride;
a second semiconductor layer formed above said first semiconductor layer, made of a second group III-V nitride and having a gate recess portion;
a third semiconductor layer that is formed between said second semiconductor layer and said first semiconductor layer, is made of a third group III-V nitride and absorbs stress caused between said second semiconductor layer and said first semiconductor layer;
a gate electrode formed on said first semiconductor layer in said gate recess portion; and
ohmic electrodes formed on said second semiconductor layer on both sides of said gate electrode.

10. The field effect transistor of claim 9,
wherein said third semiconductor layer is made of an amorphous film or a polycrystalline film.

11. The field effect transistor of claim 9,
wherein said third semiconductor layer is grown at a lower growth temperature than said first semiconductor layer.

12. A field effect transistor comprising:
a first semiconductor layer made of a first group III-V nitride;
a second semiconductor layer formed on said first semiconductor layer, made of a second group III-V nitride and having a gate recess portion;
a gate electrode formed on said first semiconductor layer in said gate recess portion;
ohmic electrodes formed on said second semiconductor layer on both sides of said gate electrode; and
a stress reducing film for covering a bottom and a sidewall of said gate recess portion and causing stress in a direction for cancelling stress applied by said second semiconductor layer to said first semiconductor layer.
